(19) United States
(12) Patent Application Publication
(10) Pub. No.: US 2025/0196472 A1
(43) Pub. Date: Jun. 19, 2025

(54) ROLL-BONDED LAMINATE AND METHOD FOR PRODUCING THE SAME

(71) Applicant: TOYO KOHAN CO., LTD., Tokyo (JP)

(72) Inventors: Kota SADAKI, Kudamatsu-shi, Yamaguchi (JP); Teppei KUROKAWA, Kudamatsu-shi, Yamaguchi (JP); Yoshikazu MARUHASHI, Kudamatsu-shi, Yamaguchi (JP)

(73) Assignee: TOYO KOHAN CO., LTD., Tokyo (JP)

(21) Appl. No.: 18/848,999

(22) PCT Filed: Mar. 28, 2023
(86) PCT No.: PCT/JP2023/012379

§ 371 Date: Sep. 20, 2024

(30) Foreign Application Priority Data
Mar. 31, 2022 (JP) 2022-058644

(51) Int. Cl. B32B 15/01; B23K 20/233; B23K 20/24; B23K 35/02

(52) U.S. Cl. CPC B32B 15/017; B23K 20/2333; B23K 20/24; B23K 35/0238

(57) ABSTRACT

A roll-bonded laminate having both high peel strength and high tolerance to bonding or bending work is provided. The roll-bonded laminate is composed of an aluminum layer and a copper layer, which is free of an intermetallic compound containing aluminum and copper at the interface between the aluminum layer and the copper layer, and has a peel strength of higher than 10 N/cm. A method for producing such roll-bonded laminates is also provided.

### TECHNICAL FIELD

The present invention relates to a roll-bonded laminate and a method for producing the same.

### BACKGROUND ART

A power module is used for a wide variety of products, such as industrial equipment, home electrical appliances, and information terminals. For a bonding wire or a bonding ribbon of a power module, various metallic materials are used. As such metallic materials, a roll-bonded laminate comprising two or more types of metal plates or metal foils laminated on top of each other is known (also referred to as a metal-laminated material or clad material). A roll-bonded laminate is a sophisticated metallic material with multiple properties that cannot be achieved with the use of a single material. For example, a roll-bonded laminate composed of an aluminum layer and a copper layer has been studied (Patent Literature 1 to Patent Literature 5).

A roll-bonded laminate used for a bonding wire or a bonding ribbon of a power module is required to have a wide variety of properties in accordance with application of a power module. For example, a power module is required to have high peel strength (it is also referred to as “bonding strength”) and have high tolerance to bonding or bending work. In general, a conventional roll-bonded laminate composed of an aluminum layer and a copper layer was required to be subjected to thermal treatment at a given temperature or higher in order to achieve sufficiently high peel strength of the roll-bonded laminate. This thermal treatment, however, results in generation of an intermetallic compound containing aluminum and copper at the interface between the aluminum layer and the copper layer, disadvantageously. The presence of an intermetallic compound at the interface of the roll-bonded laminate may cause adverse effects on the roll-bonded laminate, such as lowered peel strength and cracking or peeling upon bonding or bending work.

### CITATION LIST

### Patent Literature

Patent Literature 1: JP 2012-227241 A
Patent Literature 2: WO 2011/155379
Patent Literature 3: JP 2015-226928 A
Patent Literature 4: WO 2016/63744
Patent Literature 5: JP 2003-80621 A

### SUMMARY OF INVENTION

### Technical Problem

As described above, it was difficult for a conventional roll-bonded laminate composed of an aluminum layer and a copper layer to have high peel strength and high tolerance to bonding or bending work according to the circumstances. Therefore, it is an object of the present invention to provide a roll-bonded laminate that has achieved both high peel strength and high tolerance to bonding or bending work.

### Solution to Problem

The present inventors have conducted concentrated studies in order to attain the above object. As a result, they discovered that the roll-bonded laminate produced by surface-activated bonding while regulating thermal treatment conditions would achieve both high peel strength and high tolerance to bonding or bending work. This has led to the completion of the present invention.

Specifically, the present invention is summarized as follows.
(1) A roll-bonded laminate composed of an aluminum layer and a copper layer, which is free of an intermetallic compound containing aluminum and copper at the interface between the aluminum layer and the copper layer, and which has peel strength of higher than 10 N/cm.
(2) The roll-bonded laminate according to (1), wherein hardness (HV) of the aluminum layer is 40 or lower.
(3) The roll-bonded laminate according to (1) or (2), wherein surface roughness (Rz) of the aluminum layer is 0.5 μm or lower.
(4) The roll-bonded laminate according to any of (1) to (3), wherein the aluminum is 1000 series pure aluminum as specified by JIS.
(5) The roll-bonded laminate according to any of (1) to (4), wherein hardness (HV) of the copper layer is 130 or lower.
(6) The roll-bonded laminate according to any of (1) to (5), wherein the copper is 1000 series pure copper as specified by JIS.
(7) The roll-bonded laminate according to any of (1) to (6), wherein a ratio of hardness of the copper layer to hardness of the aluminum layer (hardness of the copper layer/hardness of the aluminum layer) is 1.0 to 5.0.
(8) The roll-bonded laminate according to any of (1) to (7), which is in a form of a wire or a ribbon.
(9) A method for producing the roll-bonded laminate according to any of (1) to (8) comprising:
   a step of subjecting an aluminum plate to sputter etching;
   a step of subjecting a copper plate to sputter etching; and
   a step of subjecting the sputter etched surface of the aluminum plate to pressure bonding to the sputter etched surface of the copper plate at a reduction ratio of the roll-bonded laminate of 3% or higher,
   wherein, following the step of pressure bonding, thermal treatment is not carried out or is carried out at a temperature lower than 250° C.
(10) A bonding wire or a bonding ribbon comprising the roll-bonded laminate according to any of (1) to (8).

This description includes part or all of the content as disclosed in Japanese Patent Application No. 2022-058644, which is a priority document of the present application.

### Advantageous Effects of Invention

The present invention can provide a roll-bonded laminate that has achieved both high peel strength and high tolerance to bonding or bending work.

### BRIEF DESCRIPTION OF DRAWINGS

FIG. 1A to FIG. 1D each show the results of an inspection performed in the examples as to the presence or absence of an intermetallic compound. FIG. 1A shows an SEM image (2000×) at the cross section of the roll-bonded laminate of Example 1. FIG. 1B shows an SEM image (2000×) at the cross section of the roll-bonded laminate of Example 2.

FIG. 1A to FIG. 1D each show the results of an inspection performed in the examples as to the presence or absence of an intermetallic compound. FIG. 1C shows an SEM image (2000×) at the cross section of the roll-bonded laminate of Comparative Example 1. FIG. 1D shows an SEM image (2000×) at the cross section of the roll-bonded laminate of Comparative Example 4.

FIG. 2A to FIG. 2C each show the results of an inspection performed in the examples as to the presence or absence of a crack caused by draw-bending. FIG. 2A shows an SEM image (2000×) at the cross section of the roll-bonded laminate of Example 1. FIG. 2B shows an SEM image (2000×) at the cross section of the roll-bonded laminate of Example 2. FIG. 2C shows an SEM image (2000×) at the cross section of the roll-bonded laminate of Comparative Example 1.

### DESCRIPTION OF EMBODIMENTS

Hereafter, the present invention is described in detail. The present invention relates to a roll-bonded laminate of a bi-layer structure composed of an aluminum layer and a copper layer. Specifically, the present invention relates to a roll-bonded laminate composed of an aluminum layer and a copper layer directly laminated on top of each other.

Aluminum used for an aluminum layer may be pure aluminum or an aluminum alloy. From the viewpoint of bending workability or conductivity upon application thereof for a bonding wire, bonding ribbon, or the like, pure aluminum is preferable.

Purity of pure aluminum is generally 99.0% by mass or higher, and preferably 99.5% by mass or higher. The total content of additive metal elements other than aluminum in pure aluminum is generally 1.0% by mass or less, preferably 0.7% by mass or less, more preferably 0.5% by mass or less, and particularly preferably 0.3% by mass or less. An example of pure aluminum that can be used is 1000 series pure aluminum as specified by JIS (JIS-H4000), with A1100, A1N30, A1050, A1085, and A1N99 being preferable.

As an aluminum alloy, an aluminum alloy in which the total content of metal elements other than aluminum exceeds 1% by mass can be used. For example, an aluminum alloy in which the total content of at least one additive metal element selected from among Mg, Mn, Si, and Cu exceeds 1% by mass can be used.

For example, aluminum alloys specified by JIS, such as Al-Cu-base alloy (2000 series), Al-Mn-base alloy (3000 series), Al-Si-base alloy (4000 series), Al-Mg-base alloy (5000 series), Al-Mg—Si-base alloy (6000 series), and Al-Zn—Mg-base alloy (7000 series), can be used. From the viewpoint of press workability, strength, and corrosion resistance, aluminum alloys of 3000 series, 5000 series, 6000 series, and 7000 series are preferable. From the viewpoint of the strength and conductivity, in particular, aluminum alloys of 3000 series are more preferable.

In general, an aluminum layer with thickness of at least 0.01 mm is applicable. From the viewpoint of workability and ease of handling of the roll-bonded laminate, the lower limit is preferably 0.03 mm or more. When strength is further required, the lower limit is more preferably 0.05 mm or more. From the viewpoint of weight reduction and cost, thickness of the aluminum layer is preferably 0.1 mm or less, more preferably 0.5 mm or less, and particularly preferably 0.3 mm or less. Thickness of the aluminum layer is preferably 0.01 mm to 1.0 mm, more preferably 0.01 mm to 0.5 mm, and particularly preferably 0.03 mm to 0.3 mm. Thickness of the aluminum layer is determined by obtaining an optical microscopic photograph at the cross section of the roll-bonded laminate, measuring thickness of the aluminum layer at arbitrary 10 points in the optical microscopic photograph, and calculating the average thickness.

Hardness (HV) of an aluminum layer is not particularly limited, and it is generally 80 or lower. From the viewpoint of bending workability, HV is preferably 60 or lower, more preferably 40 or lower, and particularly preferably 30 or lower. By softening an aluminum layer to have hardness (HV) of 30 or lower, in particular, a load upon ultrasonic bonding of a roll-bonded laminate to a semiconductor chip can be reduced when, for example, the roll-bonded laminate is used for a bonding wire or a bonding ribbon of a power module. This can reduce a damage on a semiconductor chip. The lower limit of hardness (HV) of the aluminum layer is not particularly limited and the lower limit is generally 10 or higher. From the viewpoint of strength and ease of handling, the lower limit of HV is preferably 15 or higher, more preferably 20 or higher, and particularly preferably 25 or higher. Hardness (HV) of the aluminum layer is preferably 15 to 60, more preferably 15 to 40, and particularly preferably 15 to 30. Hardness (HV) of the aluminum layer can be measured with the use of the Micro Vickers hardness tester (load: 50 gf) in accordance with JIS Z 2244 (Vickers hardness test-Test method).

Surface roughness (Ra) of an aluminum layer is not particularly limited, and it is preferably 0.5 μm or less, more preferably 0.1 μm or less, and particularly preferably 0.05 m or less. Surface roughness (Ra) can be determined with the use of SURFCOM 1400D-3DF (Tokyo Seimitsu Co., Ltd.) in accordance with JIS-B0601-1994.

Surface roughness (Rz) of an aluminum layer is not particularly limited, and it is preferably 0.5 μm or less, more preferably 0.2 μm or less, and particularly preferably 0.1 μm or less. Surface roughness (Rz) can be determined with the use of SURFCOM 1400D-3DF (Tokyo Seimitsu Co., Ltd.) in accordance with JIS-B0601-1994.

Surface roughness (Ra) and/or (Rz) of the aluminum layer is preferably adjusted within the range described above, so that a roll-bonded laminate is sufficiently adhered to a semiconductor chip upon ultrasonic bonding when, for example, the roll-bonded laminate is used for a bonding wire or a bonding ribbon of a power module.

Copper used for a copper layer may be pure copper or a copper alloy. From the viewpoint of bending workability or conductivity upon application thereof for a bonding wire or a bonding ribbon, pure copper is preferable.

Purity of pure copper is generally 99.0% by mass or higher, preferably 99.5% by mass or higher, and more preferably 99.9% by mass or higher. The total content of additive metal elements other than copper in pure copper is generally 1.0% by mass or less, preferably 0.5% by mass or less, more preferably 0.3% by mass or less, and particularly preferably 0.1% by mass or less. An example of pure copper that can be used is 1000 series pure copper as specified by JIS. Specific examples of pure copper that can be used include oxygen-free copper as specified by JIS-H3510 (C1011) or JIS-H3100 (C1020) and tough pitch copper as specified by JIS-H3100 (C1100).

As a copper alloy, a copper alloy in which the total content of metal elements other than copper exceeds 1% by mass can be used. For example, a copper alloy in which the total content of at least one additive metal element selected from among Sn, Mn, Cr, Zn, Zr, Ni, Si, Mg, and Ag as a metal element other than copper exceeds 1% by mass can be used.

In general, a copper layer with thickness of at least 0.01 mm is applicable. From the viewpoint of workability and ease of handling of the roll-bonded laminate, the lower limit is preferably 0.03 mm or more. When strength is further required, the lower limit is more preferably 0.05 mm or more. From the viewpoint of weight reduction and cost, thickness of the copper layer is preferably 1.0 mm or less, more preferably 0.5 mm or less, and particularly preferably 0.3 mm or less. Thickness of the copper layer is preferably 0.01 mm to 1.0 mm, more preferably 0.01 mm to 0.5 mm, and particularly preferably 0.03 mm to 0.3 mm. Thickness of the copper layer can be determined in the same manner as in the case of the aluminum layer.

Hardness (HV) of a copper layer is not particularly limited, and it is generally 150 or lower. From the viewpoint of bending workability, HV is preferably 140 or lower, and more preferably 130 or lower. When the roll-bonded laminate is used for application, such as a lead wire, which requires flexibility, hardness (HV) of the copper layer is preferably 85 or lower, more preferably 70 or lower, and particularly preferably 65 or lower. By softening a copper layer to have hardness (HV) of 65 or lower, in particular, a load upon ultrasonic bonding of a roll-bonded laminate to a semiconductor chip can be reduced as in the case of the aluminum layer described above. This can reduce a damage on a semiconductor chip. The lower limit of hardness (HV) of the copper layer is not particularly limited. From the viewpoint of strength and ease of handling, HV is preferably 40 or more, more preferably 50 or more, and particularly preferably 60 or more. Hardness (HV) of the copper layer is preferably 40 to 140, more preferably 40 to 130, and particularly preferably 40 to 85. Hardness of the copper layer can be determined in the same manner as in the case of the aluminum layer.

The ratio of hardness of the copper layer to hardness of the aluminum layer (hardness of the copper layer/hardness of the aluminum layer) (hereafter, it is also referred to as “the hardness ratio”) is preferably closer to 1 because of high tolerance to harder bending work. The ratio of hardness of the copper layer to hardness of the aluminum layer is preferably 1.0 to 5.0, more preferably 1.0 to 4.0, and particularly preferably 1.5 to 3.5. When the hardness ratio is within such range, hardness of the copper layer to hardness of the aluminum layer is balanced, and generation of a crack and spreading of a crack can be suppressed under harder bending work conditions. The roll-bonded laminate according to the present invention is free of an intermetallic compound at the interface and has high tolerance to bending work. By regulating the hardness ratio as described above, accordingly, the roll-bonded laminate can be more tolerant to harder bending work. In contrast, the roll-bonded laminate that has an intermetallic compound at the interface and has the hardness ratio close to 1, such as 1.0 to 2.0, causes cracking at an early stage, and the roll-bonded laminate is broken because of spreading of the crack. That is, such roll-bonded laminate is less tolerant to harder bending work.

Surface roughness (Ra) of a copper layer is not particularly limited, and it is preferably 0.5 μm or less, more preferably 0.1 μm or less, and particularly preferably 0.05 μm or less. Surface roughness (Ra) of the copper layer can be determined in the same manner as in the case of the aluminum layer.

Surface roughness (Rz) of a copper layer is not particularly limited, and it is preferably 0.5 μm or less, more preferably 0.2 μm or less, and particularly preferably 0.1 μm or less. Surface roughness (Rz) of the copper layer can be determined in the same manner as in the case of the aluminum layer.

Surface roughness (Ra) and/or (Rz) of the copper layer is preferably adjusted within the range described above, so that a roll-bonded laminate is sufficiently adhered to a semiconductor chip upon ultrasonic bonding as in the case of the aluminum layer described above.

The roll-bonded laminate according to the present invention is of a bi-layer structure composed of an aluminum layer and a copper layer. The roll-bonded laminate according to the present invention is composed of an aluminum layer and a copper layer directly laminated on top of each other. The roll-bonded laminate according to the present invention does not have any other layer (e.g., a plated layer) between the aluminum layer and the copper layer.

The roll-bonded laminate according to the present invention is free of an intermetallic compound at the interface between the aluminum layer and the copper layer. In the present invention, the term “intermetallic compound” refers to an intermetallic compound containing aluminum and copper. When the roll-bonded laminate is free of an intermetallic compound at the interface between the aluminum layer and the copper layer, the roll-bonded laminate becomes more tolerant to bonding or bending work. In the present invention, the state “is free of an intermetallic compound at the interface” is the state that a product with thickness of 0.1 μm or more is not formed at the interface when it is possible to determine the presence or absence of a product generated at the interface by observing the interface at 100-fold to 10,000-fold magnification (e.g., 2,000-fold magnification).

The roll-bonded laminate according to the present invention has peel strength of higher than 10 N/cm. When the roll-bonded laminate has peel strength of higher than 10 N/cm, the aluminum layer can be sufficiently bonded to the copper layer. Thus, the roll-bonded laminate can be used without peeling of layers at the time of bonding or bending work. Peel strength of the roll-bonded laminate is preferably 15 N/cm or higher, more preferably 20 N/cm or higher, further preferably 25 N/cm or higher, and particularly preferably 30 N/cm or higher.

In the present invention, peel strength of a roll-bonded laminate was determined by preparing test pieces, each with a width of 20 mm, from the roll-bonded laminate, partly peeling the aluminum layer from the copper layer, fixing the thick or hard layer side, pulling the other layer toward the direction opposite by 180 degrees from the fixed side, and measuring a force required to peel (unit: N/cm). In similar tests, no change is observed in peel strength if a width of the test pieces is between 10 mm and 30 mm.

Thickness of the roll-bonded laminate according to the present invention is not particularly limited, and it is generally 0.015 mm to 1.0 mm. The upper limit is preferably 0.8 mm or less, more preferably 0.5 mm or less, and particularly preferably 0.3 mm or less. The lower limit is preferably 0.02 mm or more, and more preferably 0.1 mm or more. Thickness of the roll-bonded laminate is preferably 0.02 mm to 0.8 mm, and particularly preferably 0.05 mm to 0.3 mm. Thickness of the roll-bonded laminate is a total thickness of the aluminum layer and the copper layer. Thickness of the roll-bonded laminate is determined by measuring thickness of the roll-bonded laminate at arbitrary 10 points with the use of, for example, a micrometer, and calculating the average thickness.

The form of the roll-bonded laminate according to the present invention is not particularly limited. Examples thereof include a plate, a foil, a tape, a ribbon, a wire, a ring, and a coil. The roll-bonded laminate according to the present invention preferably has high peel strength and high tolerance to bonding or bending work, and it is preferably in a form of a wire or a ribbon.

The present invention also includes a method for producing the roll-bonded laminate described above. In the present invention, a roll-bonded laminate is produced by surface-activated bonding. Specifically, the method for producing the roll-bonded laminate according to the present invention comprises: a step of subjecting an aluminum plate to sputter etching; a step of subjecting a copper plate to sputter etching; and a step of subjecting the sputter etched surface of the aluminum plate to pressure bonding to the sputter etched surface of the copper plate at a reduction ratio of the roll-bonded laminate of 3% or higher, wherein, following the step of pressure bonding, thermal treatment is not carried out or is carried out at a temperature lower than 250° C., and preferably at 220° C. or lower.

An aluminum plate used in the method for producing the roll-bonded laminate according to the present invention is the plate material composed of pure aluminum or an aluminum alloy as described for the aluminum layer of the roll-bonded laminate.

In general, an aluminum plate with thickness of at least 0.01 mm is applicable. From the viewpoint of workability and ease of handling of the roll-bonded laminate, the lower limit is preferably 0.03 mm or more. When strength is further required, the lower limit is preferably 0.05 mm or more. From the viewpoint of weight reduction and cost, thickness of the aluminum plate is preferably 1.0 mm or less, more preferably 0.5 mm or less, and particularly preferably 0.3 mm or less. Thickness of the aluminum plate is preferably 0.01 mm to 1.0 mm, more preferably 0.01 mm to 0.5 mm, and particularly preferably 0.03 mm to 0.3 mm. Thickness of the aluminum plate can be determined with the use of, for example, a micrometer, and it is determined by measuring thickness of the aluminum plate at randomly selected 10 points on the surface of the aluminum plate and calculating the average thickness.

Hardness (HV) of an aluminum plate is not particularly limited, and HV is generally 80 or lower. From the viewpoint of bending workability, HV is preferably 60 or lower, more preferably 40 or lower, and particularly preferably 30 or lower. Via surface-activated bonding, a soft aluminum plate can be laminated while substantially maintaining the hardness thereof. The lower limit of hardness (HV) of the aluminum plate is not particularly limited, and the lower limit is generally 10 or higher. From the viewpoint of strength and ease of handling, HV is preferably 15 or higher, and particularly preferably 20 or higher. Hardness (HV) of the aluminum plate is preferably 15 to 60, and more preferably 15 to 40. In the present invention, hardness of the aluminum plate can be determined in the same manner as in the case of the aluminum layer of the roll-bonded laminate.

A copper plate used in the method for producing the roll-bonded laminate according to the present invention is the plate material composed of pure copper or a copper alloy as described for the copper layer of the roll-bonded laminate.

In general, a copper plate with thickness of at least 0.01 mm is applicable. From the viewpoint of workability and ease of handling of the roll-bonded laminate, the lower limit is preferably 0.03 mm or more. When strength is further required, the lower limit is more preferably 0.05 mm or more. From the viewpoint of weight reduction and cost, thickness of the copper plate is preferably 1.0 mm or less, more preferably 0.5 mm or less, and particularly preferably 0.3 mm or less. Thickness of the copper plate is preferably 0.01 mm to 1.0 mm, more preferably 0.01 mm to 0.5 mm, and particularly preferably 0.03 mm to 0.3 mm. Thickness of the copper plate can be determined in the same manner as in the case of the aluminum plate.

Hardness (HV) of a copper plate is not particularly limited, and it is generally 150 or lower. From the viewpoint of bending workability, HV is preferably 140 or lower, and particularly preferably 130 or lower. The lower limit of hardness (HV) of the copper plate is not particularly limited. From the viewpoint of strength and ease of handling, HV is preferably 40 or more, more preferably 50 or more, and particularly preferably 60 or more. Hardness (HV) of the copper plate is preferably 40 to 140, and more preferably 40 to 130. In the present invention, hardness of the copper plate can be determined in the same manner as in the case of the aluminum layer of the roll-bonded laminate.

In the method of production according to the present invention, each of the aluminum plate and the copper plate are first subjected to sputter etching (the step of sputter etching treatment).

Specifically, sputter etching is carried out by preparing an aluminum plate and a copper plate as long coils with a width of 100 mm to 600 mm, designating the aluminum plate bonded to the copper plate as a ground-connected electrode, applying an alternating current of 1 MHz to 50 MHz to a region between the ground-connected electrode and the other insulated electrode to generate a glow discharge, and adjusting an area of the electrode exposed to the plasma generated by the glow discharge to one third or less of the area of the other electrode. During sputter etching, the ground-connected electrode is in the form of a cooling roll, which prevents the transfer materials from temperature increase.

Sputter etching treatment is intended to completely remove substances adsorbed to the surfaces and remove a part of or the entire oxide film on the surfaces by sputtering the surfaces of the aluminum plate and of the copper plate to be bonded to each other with inert gas in vacuum. It is not necessary to completely remove the oxide film, and the aluminum layer can be sufficiently bonded to the copper plate in the presence of a remaining part of the oxide film. By the presence of a remaining part of the oxide film, the duration of the sputter etching treatment is shortened to a significant extent and productivity is improved, compared to the productivity achieved when the oxide film is completely removed. Examples of inert gas that can be applied include argon, neon, xenon, krypton, and a mixed gas comprising at least one of the inert gases mentioned above. Substances adsorbed to the surface of the aluminum plate or the copper plate can be completely removed with the etching amount of about 1 nm.

In the case of a single plate, for example, the aluminum plate can be subjected to sputter etching in vacuum at a plasma output of 100 W to 1 kW for 1 to 50 minutes. In the case of a long material such as a line material, for example, it can be subjected to sputter etching in vacuum at a plasma output of 100 W to 10 kW and a line velocity of 1 m/min to 30 m/min. While a higher degree of vacuum is preferable in order to prevent substances from being readsorbed to the surface, a degree of vacuum of, for example, 1×10⁻⁵ Pa to 10 Pa is sufficient. In sputter etching, temperature of the aluminum plate is preferably maintained at ordinary temperature to 150° C. In the present invention, ordinary temperature is 15° C. to 25° C.

In the case of a single plate, for example, the copper plate can be subjected to sputter etching in vacuum at a plasma output of 100 W to 1 kW for 1 to 50 minutes. In the case of a long material such as a line material, for example, it can be subjected to sputter etching at a plasma output of 100 W to 10 kW and a line velocity of 1 m/min to 30 m/min. While a higher degree of vacuum is preferable in order to prevent substances from being readsorbed to the surface, a degree of vacuum of, for example, 1×10⁻⁵ Pa to 10 Pa is sufficient. In sputter etching, temperature of the copper plate is preferably maintained at ordinary temperature to 150° C.

Subsequently, the sputter etched surfaces (i.e., the surfaces to be bonded) of the aluminum plate and the copper plate in the manner described above are subjected to pressure bonding such as roll bonding at a reduction ratio of the roll-bonded laminate of 3% or higher to bond the aluminum plate and the copper plate (a step of bonding).

A reduction ratio of the roll-bonded laminate is 3% or higher, preferably 4% or higher, more preferably 4.5% or higher, and particularly preferably 5% or higher. When a reduction ratio of the roll-bonded laminate is 3% or higher, the roll-bonded laminate with sufficiently high peel strength can be obtained. The upper limit of the reduction ratio of the roll-bonded laminate is generally 10% or lower, from the viewpoint of, for example, shape control and hardness, preferably 8% or lower, and particularly preferably 6% or lower. The reduction ratio of the roll-bonded laminate is preferably 3% to 10%, more preferably 3% to 8%, and particularly preferably 3% to 6%. A reduction ratio of the roll-bonded laminate is determined based on the total thickness of the aluminum plate and the copper plate before bonding and the thickness of the final form of the roll-bonded laminate in accordance with the formula: (total thickness of the aluminum plate and the copper plate before bonding—thickness of the final form of the roll-bonded laminate)/total thickness of the aluminum plate and the copper plate before bonding).

A line pressure load for roll bonding is not particularly limited. It may be determined to achieve a given reduction ratio of the roll-bonded laminate. For example, a line pressure load can be adjusted within a range of 0.1 tf/cm to 10.0 tf/cm. When a diameter of a pressure roll is 300 mm to 400 mm, for example, a line pressure load for roll bonding is preferably 0.1 tf/cm to 3.0 tf/cm, more preferably 0.3 tf/cm to 3.0 tf/cm, and particularly preferably 0.3 tf/cm to 1.8 tf/cm. When a roll diameter is increased or the aluminum plate and the copper plate are thick before bonding, however, it is occasionally necessary to increase a line pressure load to maintain a pressure that is necessary to achieve a given reduction ratio, and the line pressure load is not limited thereto.

At the time of bonding, temperature is not particularly limited. For example, bonding is carried out at ordinary temperature to 150° C.

Bonding is preferably carried out in the non-oxidizing atmosphere, such as in an inert gas atmosphere (e.g., Ar), so as to prevent oxygen from being readsorbed onto the surface of the aluminum plate and that of the copper plate and to prevent the bonding strength therebetween from lowering.

In the method of production according to the present invention, on the roll-bonded laminate obtained by bonding the aluminum plate to the copper plate in the manner described above, thermal treatment is not carried out, or in case that thermal treatment is carried out, the thermal treatment is carried out at a temperature lower than 250° C., and preferably at 220° C. or lower. Since regulation of thermal treatment can suppress generation of an intermetallic compound, the roll-bonded laminate has high peel strength and high tolerance to bonding or bending work. Whether or not the roll-bonded laminate is subjected to thermal treatment can be determined in accordance with application of the roll-bonded laminate. When thermal treatment is carried out at 220° C. or lower, for example, peel strength of the roll-bonded laminate can further be enhanced, and a copper layer can be softened. By softening the copper layer, in particular, the hardness ratio of the aluminum layer to the copper layer can be adjusted within the range indicated above. Thus, the roll-bonded laminate is preferably used for application, such as a lead wire, which requires flexibility.

When thermal treatment is carried out, the thermal treatment temperature is lower than 250° C., and preferably at 220° C. or lower. When the thermal treatment temperature is 220° C. or lower, generation of an intermetallic compound can be suppressed. In order to achieve sufficiently high peel strength, the lower limit of the thermal treatment temperature is preferably 100° C. or higher, and more preferably 150° C. or higher. The thermal treatment temperature is preferably 100° C. to 220° C., and more preferably 150° C. to 220° C.

A duration of thermal treatment can be adequately determined in accordance with thermal treatment temperature, a size of the roll-bonded laminate subjected to thermal treatment, or the like, so as to suppress generation of an intermetallic compound. A duration of thermal treatment is, for example, 0.5 hours to 8 hours, preferably 0.5 hours to 5 hours, and particularly preferably 0.5 hours to 3 hours. If an intermetallic compound is not generated, thermal treatment may be carried out for 8 hours or longer. The term “duration of thermal treatment” refers to a duration after the temperature of the roll-bonded laminate to be subjected to thermal treatment is raised to a given level, and such duration does not include a period during which temperature of the roll-bonded laminate is raised. When thermal treatment temperature is 150° C., for example, the duration of thermal treatment is generally 0.5 hours to 8 hours. When thermal treatment temperature is 200° C., the duration of thermal treatment is generally 0.5 hours to 5 hours. When thermal treatment temperature is 220° C., the duration of thermal treatment is generally 0.5 hours to 3 hours.

The roll-bonded laminate according to the present invention does not have an intermetallic compound at the bonding interface and it has sufficiently high peel strength. Thus, the roll-bonded laminate has high tolerance to bonding or bending work. At the time of bending work under severer conditions, accordingly, cracking or peeling can be suppressed, and the roll-bonded laminate can be preferably used for applications, such as bonding wires, bonding ribbons, or lead wires. Accordingly, the present invention also encompasses a bonding wire, a bonding ribbon, and a lead wire comprising the roll-bonded laminate. The bonding wire, the bonding ribbon, and the lead wire according to the present invention can be used for a power module and other applications.

### EXAMPLES

Hereafter, the present invention is described in greater detail with reference to the examples and comparative examples, although the scope of the present invention is not limited to these examples.

### Example 1

With the use of AlN30 (thickness 0.05 mm) with hardness (HV) of 24.5 as an aluminum plate and C1020 (thickness 0.15 mm) with hardness (HV) of 122.5 as a copper plate, the aluminum plate and the copper plate were bonded to each other via surface-activated bonding to produce a roll-bonded laminate composed of an aluminum layer and a copper layer in the manner described below.

The surface of AlN30 and the surface of C1020 to be bonded to each other were subjected to sputter etching. AlN30 was subjected to sputter etching by introducing Ar as a sputter gas at 0.2 Pa and a plasma output of 300 W for 1 minute. C1020 was subjected to sputter etching by introducing Ar as a sputter gas at 0.2 Pa and a plasma output of 600 W for 1 minute.

After the sputter etching treatment, AlN30 was roll-bonded to C1020 at ordinary temperature with a roll diameter of 300 mm to 400 mm and a line pressure load of 0.9 tf/cm to 1.8 tf/cm. Thus, a roll-bonded laminate composed of an aluminum layer and a copper layer was obtained. The reduction ratio of the roll-bonded laminate was 5%.

### Example 2

The roll-bonded laminate produced in the same manner as in Example 1 was subjected to thermal treatment at 220° C. for 1 hour to produce the roll-bonded laminate of Example 2.

### Example 3

The roll-bonded laminate of Example 3 was produced in the same manner as in Example 1 except for the use of Al050 (thickness 0.1 mm) with hardness (HV) of 23.6 as an aluminum plate and C1020 (thickness 0.1 mm) with hardness (HV) of 123.5 as a copper plate. The reduction ratio of the roll-bonded laminate was 3%.

### Example 4

The roll-bonded laminate of Example 4 was produced in the same manner as in Example 3 except for the use of Al050 (thickness 0.1 mm) with hardness (HV) of 34.5 as an aluminum plate. The reduction ratio of the roll-bonded laminate was 3%.

### Comparative Example 1

The roll-bonded laminate of Comparative Example 1 was produced in the same manner as in Example 2, except that thermal treatment was carried out at 400° C. for 3 hours.

### Comparative Example 2

The roll-bonded laminate produced in the same manner as in Example 4 was subjected to thermal treatment at 350° C. for 1 hour to produce the roll-bonded laminate of Comparative Example 2.

### Comparative Example 3

The roll-bonded laminate of Comparative Example 3 was produced in the same manner as in Example 4, except that a pressure applied at the time of bonding was changed to adjust the reduction ratio of the roll-bonded laminate to 2.5%.

### Comparative Example 4

The roll-bonded laminate of Comparative Example 4 was produced in the same manner as in Example 2, except that thermal treatment was carried out at 250° C. for 1 hour.

The properties indicated below of the roll-bonded laminates of Examples 1 to 4 and Comparative Examples 1 to 4 were measured.

### [Hardness]

Hardness was measured with the use of the Micro Vickers hardness tester in accordance with JIS Z 2244 (Vickers hardness test-Test method).

### [Surface Roughness (Ra) and (Rz)]

Surface roughness (Ra) and (Rz) of the surface of the aluminum layer and that of the copper layer of the roll-bonded laminate were measured using a 3D surface roughness texture profile measuring instrument (SURFCOM 1400D-3DF, Tokyo Seimitsu Co., Ltd.) in accordance with JIS-B0601-1994.

### [Peel Strength]

Test pieces, each with a width of 20 mm, were prepared from the roll-bonded laminate, the aluminum layer was partly peeled from the copper layer, the copper layer side was fixed, and the aluminum layer was pulled toward the direction opposite by 180 degrees from the copper layer side at a tensile speed of 20 mm/min. A force required to peel the aluminum layer from the copper layer (unit: N/cm) was measured using a universal testing machine, TENSILON RTC-1350A (manufactured by Orientec Corporation).

### [Inspection of the Presence or Absence of Intermetallic Compound]

The cross section of the roll-bonded laminate was processed using a cross section polisher (CP), and the cross section was observed using a scanning electron microscope (SEM) at 2000-fold magnification to inspect the presence or absence of an intermetallic compound. In Table 1, a case in which an intermetallic compound with thickness of 0.1 μm or more is present at the interface between the aluminum layer and the copper layer is indicated as “Present,” and a case in which an intermetallic compound with thickness of 0.1 μm or more is absent is indicated as “Absent.”

### [Inspection of the Presence or Absence of Crack Caused by Draw-Bending]

Test pieces, each with a length of 50 mm and a width of 10 mm, were prepared from the roll-bonded laminates, and the prepared test pieces were gripped and fixed by a vise. Thereafter, draw-bending was performed by bending the fixed test pieces to a 90-degree angle and converting the bent test pieces back into the original form. After the cross sections of the processed roll-bonded laminates were manually polished, the cross sections were observed using the scanning electron microscope (SEM) at 2000-fold magnification, so as to inspect the presence or absence of a crack. In Table 1, a case in which a crack has occurred is indicated as “Cracked,” and a case without a crack is indicated as “Not cracked.”

### [Bend-Peel Test]

Test pieces, each with a length of 50 mm and a width of 10 mm, were prepared from the roll-bonded laminates, and the prepared test pieces were bent to a 90-degree angle and then bent to a 90-degree angle toward the direction opposite thereto using a bend tester. This process was repeated until the test pieces were broken, and whether or not layers were peeled after the test pieces had been broken was inspected. In Table 1, a case in which layers were peeled is indicated as “Peeled,” and a case in which layers were not peeled is indicated as “Not peeled.” Table 2 shows the number of times of bending until the test pieces were broken.

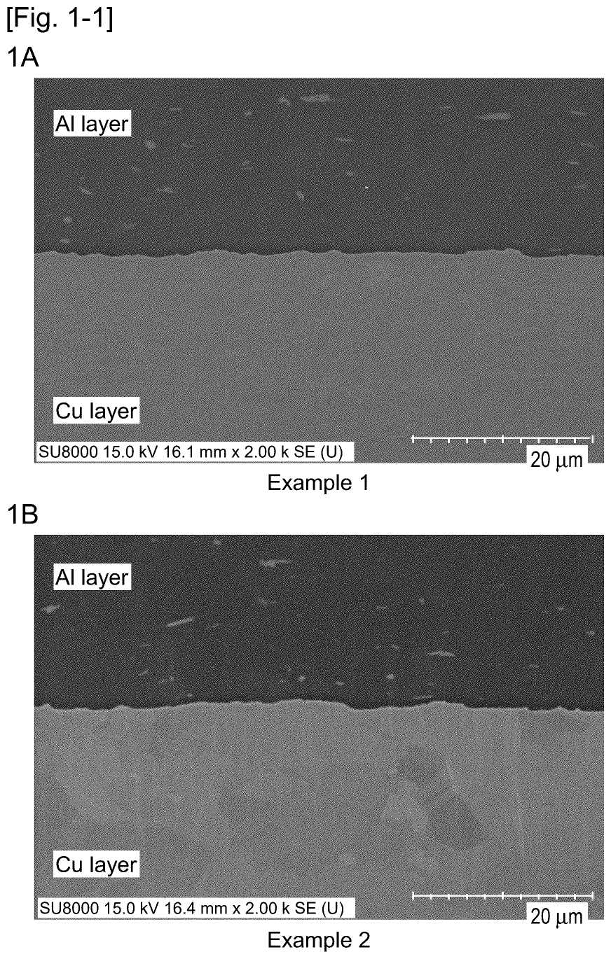

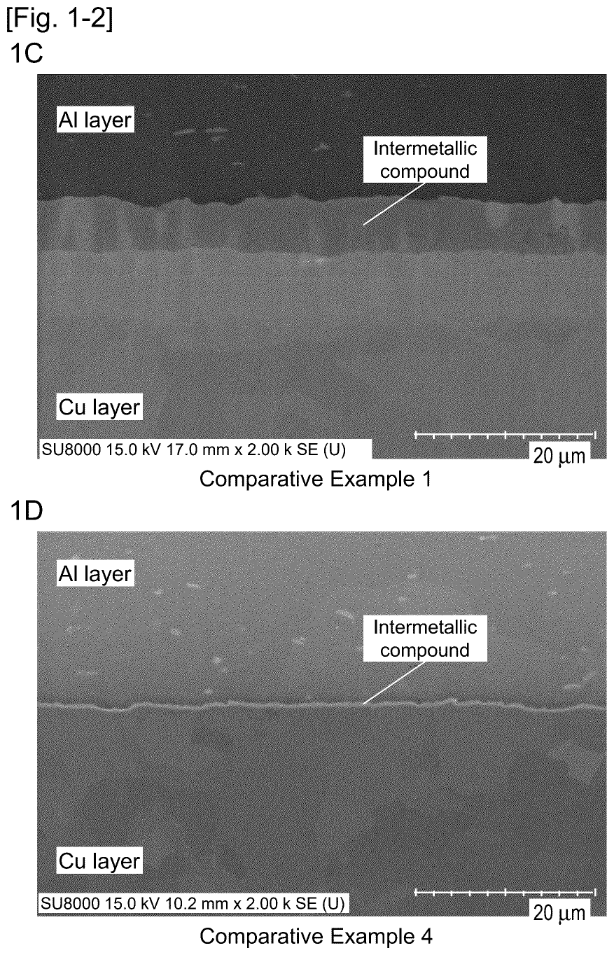

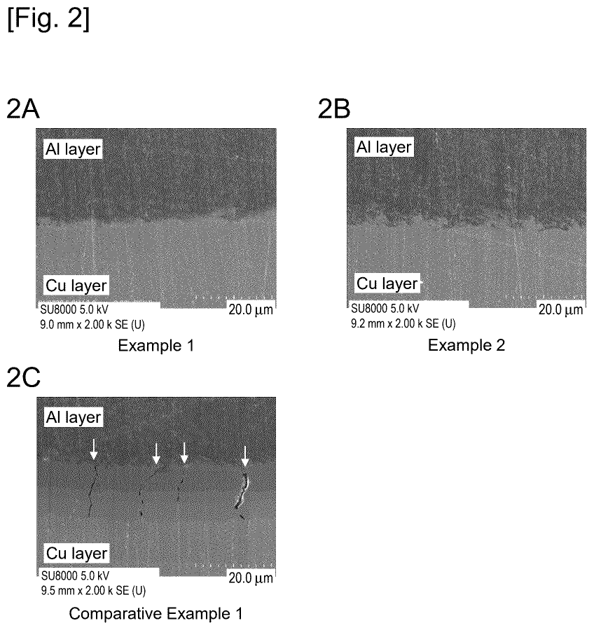

Table 1 shows the properties of the original plates of the roll-bonded laminates of Examples 1 to 4 and Comparative Examples 1 to 4 and the results of evaluation of the roll-bonded laminates of Examples 1 to 4 and Comparative Examples 1 to 4. FIG. 1A to FIG. 1D each show the results of an inspection of the presence or absence of an intermetallic compound. FIG. 1A shows an SEM image (2000×) at the cross section of the roll-bonded laminate of Example 1, FIG. 1B shows an SEM image (2000×) at the cross section of the roll-bonded laminate of Example 2, FIG. 1C shows an SEM image (2000×) at the cross section of the roll-bonded laminate of Comparative Example 1, and FIG. 1D shows an SEM image (2000×) at the cross section of the roll-bonded laminate of Comparative Example 4. FIG. 2A to FIG. 2C each show the results of an inspection of the presence or absence of a crack caused by draw-bending. FIG. 2A shows an SEM image (2000×) at the cross section of the roll-bonded laminate of Example 1, FIG. 2B shows an SEM image (2000×) at the cross section of the roll-bonded laminate of Example 2, and FIG. 2C shows an SEM image (2000×) at the cross section of the roll-bonded laminate of Comparative Example 1.

TABLE 1

| | | | Thickness of | | Hardness of | | Thermal | | Surface | |
|---|---|---|---|---|---|---|---|---|---|---|
| | | | original plate | | original plate | | treatment | | roughness | |
| | Constitution | | (mm) | | (HV) | | conditions | | Ra (μm) | |
| | Al | Cu | Al | Cu | Al | Cu | Temp. | Duration | Al layer | Cu layer |
| Ex. 1 | A1N30 | C1020 | 0.05 | 0.15 | 24.5 | 122.5 | — | — | 0.01 | 0.01 |
| Ex. 2 | A1N30 | C1020 | 0.05 | 0.15 | 24.5 | 122.5 | 220° C. | 1 hr | 0.01 | 0.01 |
| Ex. 3 | A1050 | C1020 | 0.1 | 0.1 | 23.6 | 123.5 | — | — | 0.01 | 0.01 |
| Ex. 4 | A1050 | C1020 | 0.1 | 0.1 | 34.5 | 123.5 | — | — | 0.01 | 0.01 |
| Comp. | A1N30 | C1020 | 0.05 | 0.15 | 24.5 | 122.5 | 400° C. | 3 hr | 0.01 | 0.01 |
| Ex. 1 | | | | | | | | | | |
| Comp. | A1050 | C1020 | 0.1 | 0.1 | 34.5 | 123.5 | 350° C. | 1 hr | 0.01 | 0.01 |
| Ex. 2 | | | | | | | | | | |
| Comp. | A1050 | C1020 | 0.1 | 0.1 | 34.5 | 123.5 | — | — | 0.01 | 0.01 |
| Ex. 3 | | | | | | | | | | |
| Comp. | A1N30 | C1020 | 0.05 | 0.15 | 24.5 | 122.5 | 250° C. | 1 hr | 0.01 | 0.01 |
| Ex. 4 | | | | | | | | | | |

| | Surface | | | | Crack | Peeling |
|---|---|---|---|---|---|---|
| | roughness | | Peel | | caused by | caused by |
| | Rz (μm) | | strength | Intermetallic | draw | bend-peel |
| | Al layer | Cu layer | (N/cm) | compound | bending | test |
| Ex. 1 | 0.05 | 0.06 | 30 or higher | Absent | Not cracked | Not peeled |
| Ex. 2 | 0.05 | 0.06 | 30 or higher | Absent | Not cracked | Not peeled |
| Ex. 3 | 0.05 | 0.06 | 20 | Absent | Not cracked | Not peeled |
| Ex. 4 | 0.05 | 0.06 | 20 | Absent | Not cracked | Not peeled |
| Comp. | 0.05 | 0.06 | 30 or higher | Present | Cracked | Peeled |
| Ex. 1 | | | | | | |
| Comp. | 0.05 | 0.06 | 20 | Present | Cracked | Peeled |
| Ex. 2 | | | | | | |
| Comp. | 0.05 | 0.06 | 10 | Absent | Not cracked | Peeled |
| Ex. 3 | | | | | | |
| Comp. | 0.05 | 0.06 | 30 or higher | Present | Cracked | Peeled |
| Ex. 4 | | | | | | |

As shown in Table 1, the roll-bonded laminates of Examples 1 to 4 do not have an intermetallic compound at the interface and have the peel strength of higher than 10 N/cm. That is, such roll-bonded laminates exhibit high tolerance to draw-bending work and bending work. The results of comparison between Examples 1 and 2 and Comparative Examples 1 and 4 demonstrate that, as a result of thermal treatment performed at 250° C. or higher, an intermetallic compound would be generated at the interface (see FIGS. 1A to 1D), a crack would be generated at the interface in draw-bending work (see FIGS. 2A to 2C), and peeling would occur in bending work. That is, tolerance to draw-bending work and bending work was lowered. The results of comparison between Example 4 and Comparative Example 2 in which another aluminum was used demonstrate that, as a result of thermal treatment performed at 350° C., an intermetallic compound would be generated and tolerance to draw-bending work and bending work would be lowered. In addition, the results of comparison between Example 4 and Comparative Example 3 demonstrate that sufficiently high peel strength would not be achieved if the reduction ratio of the roll-bonded laminate is low.

Table 2 shows hardness and the hardness ratio of the layers of the roll-bonded laminates, and the number of times of bending before the test pieces are broken in the bend-peel test for the roll-bonded laminates of Examples 1 to 4 and Comparative Example 1.

TABLE 2

| | Hardness of roll- | | | Number of bending |
|---|---|---|---|---|
| | bonded laminate (HV) | | Hardness ratio | before breaking |
| | Al layer | Cu layer | Cu layer/Al layer | (Number of times) |
| Ex. 1 | 27.9 | 123.7 | 4.43 | 9 |
| Ex. 2 | 26.6 | 61.2 | 2.30 | 15 |
| Ex. 3 | 28.1 | 123.9 | 4.41 | 8 |
| Ex. 4 | 35.2 | 123.9 | 3.52 | 8 |
| Comp. | 33.7 | 47 | 1.39 | 5 |
| Ex. 1 | | | | |

As shown in Table 2, the roll-bonded laminates of Examples 1 to 4 that do not have an intermetallic compound at the interface were found to be tolerant to harder bending work as the hardness ratio of the copper layer to the aluminum layer (the Cu layer/the Al layer) became closer to 1. This indicates that a crack is likely to spread from the site where a crack has occurred when a difference between hardness of the copper layer and that of the aluminum layer is large and that spreading of a crack can be suppressed because the balance in hardness of the two layers is improved as the hardness ratio becomes closer to 1. In the case of the roll-bonded laminate of Comparative Example 1 that has an intermetallic compound at the interface, the hardness ratio is close to 1; however, the roll-bonded laminate of Comparative Example 1 was broken earlier than the roll-bonded laminates of Examples 1 to 4. This indicates that a crack is generated at an early stage because of the presence of an intermetallic compound at the interface of the roll-bonded laminate of Comparative Example 1, a crack spreads to the aluminum layer and the copper layer from the site where the crack was generated, and the roll-bonded laminate is then broken. As shown in Table 2, in addition, the roll-bonded laminate of Example 2 subjected to thermal treatment at 220° C. was found to have the aluminum layer with equivalent hardness and the copper layer with significantly lower hardness, compared to the roll-bonded laminate of Example 1 that was not subjected to thermal treatment.

All publications, patents, and patent applications cited herein are incorporated herein by reference in their entirety.

1. A roll-bonded laminate composed of an aluminum layer and a copper layer, which is free of an intermetallic compound containing aluminum and copper at the interface between the aluminum layer and the copper layer, and which has peel strength of higher than 10 N/cm.

2. The roll-bonded laminate according to claim 1, wherein the hardness (HV) of the aluminum layer is 40 or lower.

3. The roll-bonded laminate according to claim 1, wherein surface roughness (Rz) of the aluminum layer is 0.5 μm or lower.

4. The roll-bonded laminate according to claim 1, wherein the aluminum is 1000 series pure aluminum as specified by JIS.

5. The roll-bonded laminate according to claim 1, wherein the hardness (HV) of the copper layer is 130 or lower.

6. The roll-bonded laminate according to claim 1, wherein the copper is 1000 series pure copper as specified by JIS.

7. The roll-bonded laminate according to claim 1, wherein a ratio of hardness of the copper layer to hardness of the aluminum layer (hardness of the copper layer/hardness of the aluminum layer) is from 1.0 to 5.0.

8. The roll-bonded laminate according to claim 1, which is in a form of a wire or a ribbon.

9. A method for producing the roll-bonded laminate according to claim 1 comprising:
subjecting an aluminum plate to sputter etching;
subjecting a copper plate to sputter etching; and
subjecting the sputter etched surface of the aluminum plate to pressure bonding to the sputter etched surface of the copper plate at a reduction ratio of the roll-bonded laminate of 3% or higher,
wherein, following pressure bonding, thermal treatment is not carried out or is carried out at a temperature lower than 250° C.

10. A bonding wire or a bonding ribbon comprising the roll-bonded laminate according to claim 1.
